(19) United States
(12) Patent Application Publication
(10) Pub. No.: US 2008/0290836 A1
(43) Pub. Date: Nov. 27, 2008

(54) Battery charger for power hand tool

(75) Inventors: Kim Y. C. Tsai, Taichung Hsien (TW); Cheng-I Teng, Taichung County (TW)

Correspondence Address: BACON & THOMAS, PLLC, 625 SLATERS LANE, FOURTH FLOOR, ALEXANDRIA, VA, 22314-1176, US

(73) Assignee: MOBILETRON ELECTRONICS CO., LTD., TAICHUNG HSIEN (TW)

(21) Appl. No.: 11/802,115

(22) Filed: May 21, 2007

(51) Int. Cl. H02J 7/00; H05K 7/20

(52) U.S. Cl. 320/114; 361/695

(57) ABSTRACT

A battery charger for charging a battery of a power hand tool includes a housing with a charging chamber for receiving the battery under charging, air vents for ventilation, and a communication hole in communication with the charging chamber, a charging circuit assembly mounted inside the housing, a fan mounted inside the housing and electrically connected to the charging circuit assembly and having a first ventilation side facing the air vents and a second ventilation side opposite to the first ventilation side, and an ventilation unit in air communication between the communication hole and the second ventilation side of the fan for guiding air out of the charging chamber to the outside of the housing through the air vents during operation of the fan and charging of a battery by the charging circuit assembly.

### BACKGROUND OF THE INVENTION

1. Field of the Invention

The present invention relates generally to accessories for power hand tools, and more particularly to a battery charger for a power hand tool, which has ventilation means for heat dissipation.

2. Description of the Related Art

A regular battery charger for power hand tool has at least one row of exhaust holes on the housing so that heat energy (hot air) can be expelled out of the housing through the exhaust holes when the battery charger is charging a battery.

The aforesaid exhaust holes simply exhausts accumulated heat energy out of the body of the battery charger. Actually when charging a battery with the battery charger, heat energy mainly comes from the battery and is accumulated at the battery and its surroundings. Because the exhaust holes are simply provided for ventilation, they do not expel hot air out of the housing of the battery charger actively, and there is a great risk of battery burnout due to excessively high temperature.

There is a kind of commercially available battery for power hand tool equipped with a temperature sensor that automatically stops charging when the charging temperature surpasses a predetermined high level. This design of battery prevents burnout upon an excessively high temperature during charging; however, the battery may be not fully charged within the expected time period. A charging delay may cause trouble to the user.

### SUMMARY OF THE INVENTION

The present invention has been accomplished under the circumstances in view. It is therefore one objective of the present invention to provide a battery charger for power hand tool, which has an excellent heat dissipation effect.

To achieve this objective of the present invention, the battery charger for charging a battery of a power hand tool comprises a housing accommodating therein a charging circuit assembly, a fan and a ventilation unit. The housing has a charging chamber for receiving a battery under charging, a plurality of air vents for ventilation, and a communication hole in communication with the charging chamber. The charging circuit assembly has a plurality of metal contacts exposed in the charging chamber for contacting the battery under charging in the charging chamber electrically. The fan is electrically connected to the charging circuit assembly and controllable by the charging circuit assembly to cause currents of air. The fan has a first ventilation side facing the air vents, and a second ventilation side opposite to the first ventilation side. The ventilation unit is in air communication between the communication hole and the second ventilation side of the fan.

In a preferred embodiment, the ventilation unit includes an air trap hood having a first opening covered on the first ventilation side of the fan, and a second opening, and an air guide tube connected between the second opening of the air trap hood and the communication hole. The fan draws air out of the charging chamber through the communication hole, the air guide tube, the air trap hood, the second ventilation side of the fan and the first ventilation side of the fan to the outside of the housing through the air vents. Alternatively, the fan draws outside air into the housing through the air vents toward the charging chamber via the first ventilation side, the second ventilation side, the air trap hood, the air guide tube and the communication hole.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is an exploded view of a battery charger for power hand tool according to a preferred embodiment of the present invention;

FIG. 2 is a partial cutaway assembly view of the battery charger for power hand tool according to the preferred embodiment of the present invention; and

FIG. 3 is a schematic sectional view of the present invention, showing the flowing direction of air.

### DETAILED DESCRIPTION OF THE INVENTION

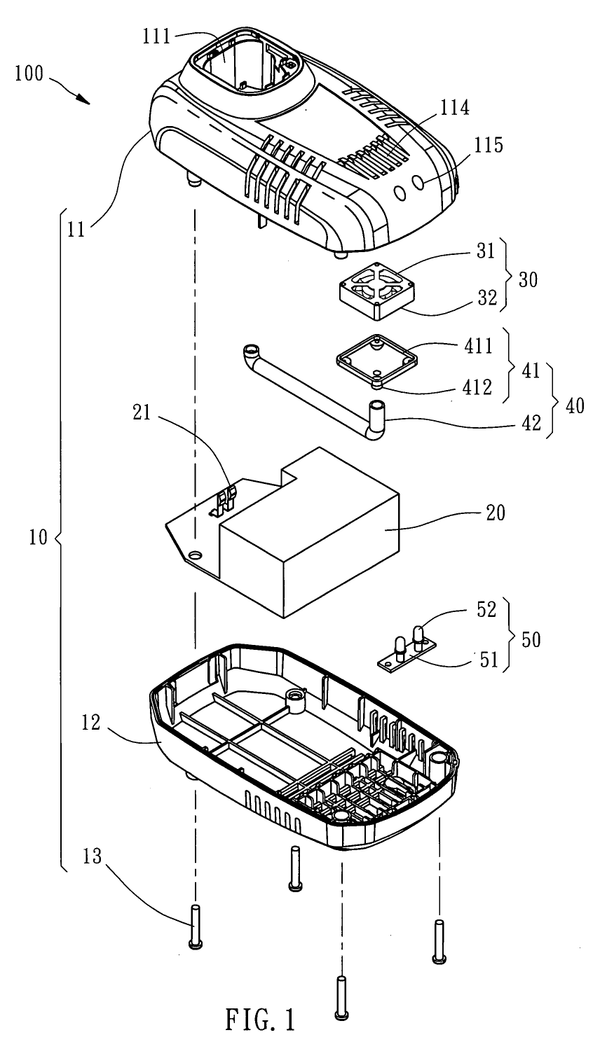

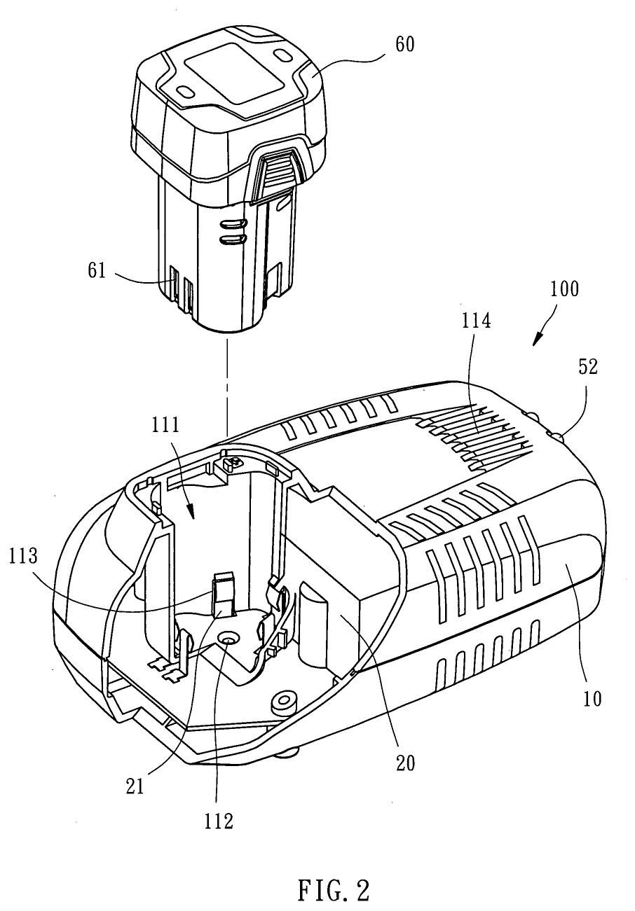

As shown in FIGS. 1-3, a battery charger 100 in accordance with a preferred embodiment of the present invention comprises a housing 10, a charging circuit assembly 20, a fan 30, a ventilation unit 40 and an indicator 50.

The housing 10 is formed of a top cover shell 11 and a bottom cover shell 12. The top cover shell 11 and the bottom cover shell 12 are fixedly fastened together with screws 13, defining an inside space. The top cover shell 11 has a recessed charging chamber 111 in the top side for receiving a battery 60 for a power hand tool, a communication hole 112 in communication between the recessed charging chamber 111 and the inside space of the housing 10, a plurality of mounting through holes 113 at one side in communication between the inside space of the housing 10 and the space outside the housing 10, and a plurality of air vents 114 and two lamp holes 115 in the top side remote from the recessed charging chamber 111.

The charging circuit assembly 20 is fixedly mounted in the inside space of the housing 10, having a plurality of metal contacts 21 respectively affixed to the mounting through holes 113 at one side of the recessed charging chamber 111 for the contact of the conducting terminals 61 of the battery 60 that is inserted into the recessed charging chamber 111 electrically so that the charging circuit assembly 20 can charge the battery 60.

The fan 30 is fixedly mounted in the inside space of the housing 10, having a first ventilation side 31 and a second ventilation side 32. The first ventilation side 31 is aimed at the air vents 114 of the housing 10. The fan 30 is electrically connected to the charging circuit assembly 20 so that the charging circuit assembly 20 provides power to drive the fan 30, drawing air from the inside space of the housing 10 through the second ventilation side 32 toward the air vents 114 via the first ventilation side 31.

The ventilation unit 40 includes an air trap hood 41 and an air guide tube 42. The air trap hood 41 is mounted in the inside space of the housing 10, having a big-area (big caliber) first opening 411 at one side and a small-area (small caliber) second opening 412 at the opposite side. The first opening 411 of the air trap hood 41 is covered on the second ventilation side 32 of the fan 30. The air guide tube 42 is mounted in the inside space of the housing 10 and connected between the second opening 412 of the air trap hood 41 and the communication hole 112 of the housing 10.

The indicator 50 includes bracket 51 and two indicator lights 52. The bracket 51 is fixedly mounted in the inside space of the housing 10. The two indicator lights 52 are LEDs (light emitting diodes) mounted in the bracket 51 and partially inserted through the lamp holes 115 of the housing and electrically connected to the charging circuit assembly 20. The indicator lights 52 are controlled to emit different colors of light so that the user knows that the battery 60 is in the charging mode or the charging of the battery 60 has completed.

After understanding of the assembly of the battery charger 100, the operation of the battery charger 100 is outlined hereinafter.

At first, the battery charger 100 is connected to an external power source, and the user can then insert the battery 60 to be charged into the recessed charging chamber 111 of the housing 10 to force the conducting terminals 61 of the battery 60 into contact with the metal contacts 21 of the charging circuit assembly 20, enabling the charging circuit assembly 20 to charge the battery 60. At this time, one indicator light 52 (red indicator light) is turned on, indicating that the battery 60 is under charging. When the battery 60 is fully charged, the other indicator light 52 (green indicator light) is turned on, indicating that the charging of the battery 60 has done.

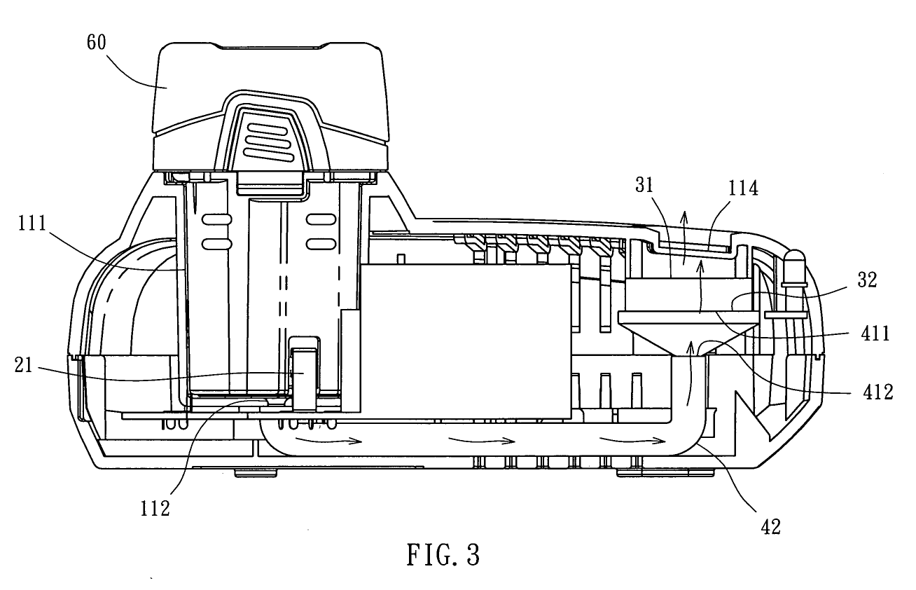

During charging of the battery 60, the charging circuit assembly 20 drives the fan 30 to induce a flow of air that goes in direction from the recessed charging chamber 111 through the communication hole 112, the air guide tube 42, the air trap hood 41, the second ventilation side 32, the first ventilation side 31 and the air vents 114 to the outside of the housing 10 (see FIG. 3), to carry heat away from the battery 60 and its surroundings, thereby lowering the temperature of the battery 60 during charging of the battery 60, eliminating the risk of battery burnout.

Further, the fan 30 can be set for full time working (i.e., to start working immediately after insertion of the battery and to stop working immediately after removal of the battery), or for working during charging of the inserted battery. Further, a temperature sensor (not shown) can be installed in the charging circuit assembly 20 and electrically connected to one metal contact 21. When the temperature of the battery 60 surpasses a predetermined value, the temperature sensor starts the fan 30. On the contrary, when the temperature of the battery 60 is below the predetermined value, the temperature sensor turns off the fan 30.

Further, because the first opening 411 of the air trap hood 41 is connected to the fan 30 and has a caliber greater then the second opening 412, the speed of the induced flow of air is accelerated when it goes through the communication hole 112, the air guide tube 42 and the second opening 412 to carry heat away from the battery 60 and its surroundings.

In the aforesaid preferred embodiment of the present invention, the second ventilation side 32 of the fan 30 is the air input side, and the first ventilation side 31 of the fan 30 is the air output side, and the first opening 411 of the air trap hood 41 is covered on the second ventilation side 32 of the fan 30 for guiding hot air out of the housing 10 through the air vents 114. Alternatively, the second ventilation side 32 of the fan 30 can be designed for air output and the first ventilation side 31 of the fan 30 can be designed for air input. In this case, the second ventilation side 32 of the fan 30 is attached to the first opening 411 of the air trap hood 41 for enabling the fan 30 to draw outside cooling air through the air vents 114 into the inside of the housing 10 toward the battery 60 and the space around the battery 60 to lower the temperature of the battery 60. Simply reversing the direction of rotation of the fan or reversing the installation direction of the fan can achieve the aforesaid two ways.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A battery charger for charging a battery of a power hand tool, the battery charger comprising:
a housing having a charging chamber for receiving a battery under charging, a plurality of air vents for ventilation, and a communication hole in communication with the charging chamber;
a charging circuit assembly mounted inside the housing and having a plurality of metal contacts exposed in the charging chamber for contacting the battery under charging in the charging chamber electrically;
a fan mounted inside the housing and electrically connected to the charging circuit assembly and controllable by the charging circuit assembly to cause currents of air, the fan having a first ventilation side facing the air vents, and a second ventilation side opposite to the first ventilation side;
a ventilation unit in air communication between the communication hole and the second ventilation side of the fan.

2. The battery charger as claimed in claim 1, wherein the communication hole is formed on a bottom side of the charging chamber.

3. The battery charger as claimed in claim 1, wherein the charging chamber has a plurality of mounting through holes for receiving the metal contacts of the charging circuit assembly.

4. The battery charger as claimed in claim 1, wherein the fan draws outside air into the housing through the air vents toward the charging chamber via the first ventilation side and the second ventilation side and then the ventilation unit and the communication hole.

5. The battery charger as claimed in claim 1, wherein the fan draws air out of the charging chamber through the communication hole and the ventilation unit and then the second ventilation side and the first ventilation side to the outside of the housing through the air vents.

6. The battery charger as claimed in claim 1, wherein the ventilation unit comprises an air trap hood having a first opening disposed at one side thereof and covered on the first ventilation side of the fan, and a second opening disposed at an opposite side thereof, and an air guide tube connected between the second opening of the air trap hood and the communication hole; wherein the first opening of the air trap hood has a diameter greater than the second opening.

7. The battery charger as claimed in claim 1, further comprising an indicator for providing a first indication signal when the charging circuit assembly is charging a battery in the charging chamber, and a second indication signal after fully charge of a battery in the charging chamber by the charging circuit assembly.

8. The battery charger as claimed in claim 7, wherein the housing comprises a plurality of lamp holes; the indicator comprises a bracket fixedly mounted inside the housing adjacent to the lamp holes, a first indicator light mounted in the bracket and inserted into one lamp hole of the housing and electrically connected to the charging circuit assembly and controllable by the charging circuit assembly to emit a first color of light, and a second indicator light mounted in the bracket and inserted into one lamp hole of the housing and electrically connected to the charging circuit assembly and controllable by the charging circuit assembly to emit a second color of light.

9. The battery charger as claimed in claim 1, wherein the charging circuit assembly comprises a temperature sensor electrically connected to one metal contact of the charging circuit assembly for detecting the temperature of the battery that is inserted into the charging chamber.

10. The battery charger as claimed in claim 9, wherein the charging circuit assembly turns on the fan when the temperature sensor detects a temperature over a predetermined value, and turns off the fan when the temperature detected by the temperature sensor is below the predetermined value.
